(19) United States
(12) Patent Application Publication
(10) Pub. No.: US 2016/0282438 A1
(43) Pub. Date: Sep. 29, 2016

(54) APPARATUS AND METHOD FOR DYNAMICALLY AND/OR LOCALLY ADJUSTING TRANSMIT GAIN AND RF SHIMMING DURING IMAGING AND SPECTROSCOPY

(71) Applicant: General Electric Company, Schenectady, NY (US)

(72) Inventors: LING SUN, BROOKFIELD, WI (US); WEI SUN, WAUKESHA, WI (US); RALPH NOESKE, BERLIN (DE); QUAN ZHU, LINCOLNSHIRE, IL (US)

(73) Assignee: GENERAL ELECTRIC COMPANY, Schenectady, NY (US)

(21) Appl. No.: 14/671,116

(22) Filed: Mar. 27, 2015

(51) Int. Cl. G01R 33/565; G01R 33/46; G01R 33/54; G01R 33/3875

(52) U.S. Cl. CPC G01R 33/5659; G01R 33/3875; G01R 33/4625; G01R 33/546

(57) ABSTRACT

An apparatus that includes an image processor that is configured to acquire a multi-slice B1 map during a pre-scan of a target object; calculate a plurality of B1 values each corresponding to one slice of the multi-slice B1 map; and adjust transmit gain for each slice of a scan of the target object, according to the B1 value or values calculated for that slice.

### BACKGROUND

1. Technical Field

Embodiments of the invention relate generally to magnetic resonance imaging and spectroscopy. Particular embodiments relate to enhancing images or spectrographic profiles obtained from magnetic resonance equipment.

2. Discussion of Art

Magnetic resonance images and/or spectrographs typically are produced by algorithms that presume perfect homogeneity of a constant magnetic field B0 that used to align spins of atoms within a target object. Homogeneity of a radio frequency magnetic field B1, the field used to perturb the spins of selected atoms within the target object, is also presumed. These algorithms rely on presumptions that, however, do not perfectly match the physics of a real magnetic resonance apparatus. In particular, these algorithms have tended to ignore, for example, inhomogeneities of intensity of the B1 magnetic field as coupled from one or a plurality of RF coils to various locations within a target object.

In this disclosure, “transmit gain” means generally an amount of electromagnetic power delivered through one or more RF coils to couple the B1 magnetic field into a target object. In other words, transmit gain implies an average energy across one or more coils. By adjusting transmit gain per slice, the base line for each slice will be changed. On the other hand, “RF shimming” means adjusting transmit amplitude and phase among a plurality of transmit coil elements to enhance homogeneity of B1 intensity among different subregions within a target object. RF shimming is on top of transmit gain adjustment, and is among the coil elements. Conventionally, both transmit gain and RF shimming have been set before undertaking a magnetic resonance scan for imaging.

As will be appreciated, it is generally desirable to account for variables (e.g., imperfections) that might cause imaging equipment to deviate from the presumptions underlying the algorithms used to produce images. In view of the above, it is desirable to provide apparatus and methods for adjusting the transmit gain and/or RF shimming of one or more RF coils, during a magnetic resonance imaging or spectroscopy scan, based on a pre-scan mapping of B1 transmit intensity.

### BRIEF DESCRIPTION

Embodiments of the invention implement a method for “dynamic” adjust of transmit gain and RF shimming in magnetic resonance imaging or spectroscopy, i.e. adjustment of transmit gain and/or RF shimming differently for different slices during a multi-slice scan. The method includes acquiring a multi-slice B1 map during a pre-scan of a target object; calculating a plurality of B1 values each corresponding to one slice of the multi-slice B1 map; and adjusting transmit gain for each slice of a scan of the target object, according to the B1 value or values calculated for that slice.

Embodiments of the invention provide an apparatus that includes a controller that is operatively connected with a magnet assembly, which defines a target volume; and an image processor that is configured to acquire a multi-slice B1 map during a pre-scan of a target object within the target volume; calculate a plurality of B1 values each corresponding to one slice of the multi-slice B1 map; and adjust transmit gain for each slice of a scan of the target object, according to the B1 value or values calculated for that slice.

Other embodiments provide an apparatus that includes an image processor that is configured to acquire a multi-slice B1 map during a pre-scan of a target object; calculate a plurality of B1 values each corresponding to one slice of the multi-slice B1 map; and adjust transmit gain for each slice of a scan of the target object, according to the B1 value or values calculated for that slice.

### DRAWINGS

The present invention will be better understood from reading the following description of non-limiting embodiments, with reference to the attached drawings wherein below:

FIG. 1 shows schematically major components of an exemplary magnetic resonance imaging (MRI) system that incorporates embodiments of the invention.

FIGS. 2 and 3 show schematically a method that is implemented by a computer system of the exemplary MRI system, according to embodiments of the invention.

FIGS. 4A-4D show graphically comparative pre-scan measurements of transmit gain and averaged values of scanned B1 receive intensity.

FIGS. 5-8 show pictorially comparative images obtained by conventional MRI scans or by MRI scans according to embodiments of the invention.

### DETAILED DESCRIPTION

Reference will be made below in detail to exemplary embodiments of the invention, examples of which are illustrated in the accompanying drawings. Wherever possible, the same reference characters used throughout the drawings refer to the same or like parts, without duplicative description.

As used herein, the term “spin” refers to a fundamental property of subatomic particles such as protons, electrons, and neutrons. Individual unpaired subatomic particles each possess +/−½ spin. The term “B0 ” refers to a constant magnetic field applied to an imaging subject in order to align the spins of atoms within the subject. The term “B1” refers to a radio-frequency magnetic field applied transverse to B0 in order to perturb the spins of atoms within the subject.

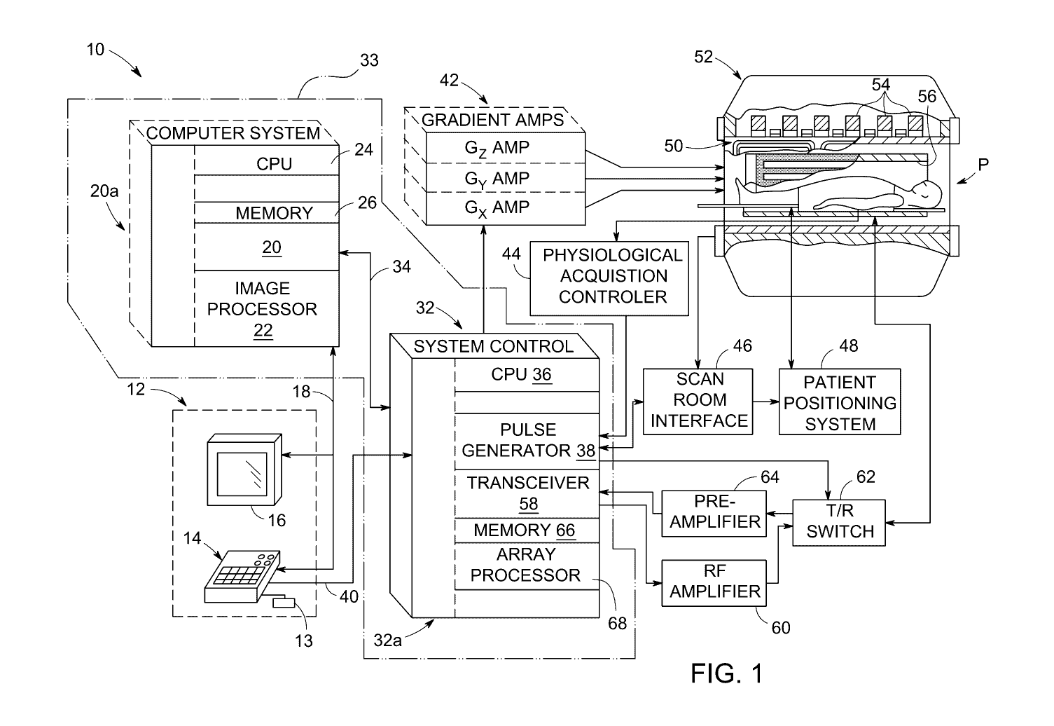

FIG. 1 shows major components of an exemplary magnetic resonance imaging (MRI) system 10 that incorporates embodiments of the present invention. The operation of the system is controlled from an operator console 12, which includes a keyboard or other input device 13, a control panel 14, and a display screen 16. The input device 13 can include a mouse, joystick, keyboard, track ball, touch activated screen, light wand, voice control, or any similar or equivalent input device, and may be used for interactive geometry prescription. The console 12 communicates through a link 18 with a separate computer system 20 that enables an operator to control the production and display of images on the display screen 16. The computer system 20 includes a number of modules that communicate with each other through a backplane 20a. The modules of the computer system 20 include an image processor module 22, a CPU module 24 and a memory module 26 that may include a frame buffer for storing image data arrays. The computer system 20 is linked to archival media devices, permanent or back-up memory storage or a network for storage of image data and programs, and communicates with a separate MRI system control 32 through a high-speed signal link 34. The computer system 20 and the MRI system control 32 collectively form an “MRI controller” 33.

The MRI system control 32 includes a set of modules connected together by a backplane 32a. These include a CPU module 36 as well as a pulse generator module 38. The CPU module 36 connects to the operator console 12 through a data link 40. It is through link 40 that the MRI system control 32 receives commands from the operator to indicate the scan sequence that is to be performed. The CPU module 36 operates the system components to carry out the desired scan sequence and produces data which indicates the timing, strength and shape of the RF pulses produced, and the timing and length of the data acquisition window. The CPU module 36 connects to several components that are operated by the MRI controller 33, including the pulse generator module 38 (which controls a gradient amplifier 42, further discussed below), a physiological acquisition controller (“PAC”) 44, and a scan room interface circuit 46.

The CPU module 36 receives patient data from the physiological acquisition controller 44, which receives signals from a number of different sensors connected to the patient, such as ECG signals from electrodes attached to the patient. And finally, the CPU module 36 receives from the scan room interface circuit 46, signals from various sensors associated with the condition of the patient and the magnet system. It is also through the scan room interface circuit 46 that the MRI controller 33 commands a patient positioning system 48 to move the patient or client C to a desired position for the scan.

The pulse generator module 38 operates the gradient amplifiers 42 to achieve desired timing and shape of the gradient pulses that are produced during the scan. The gradient waveforms produced by the pulse generator module 38 are applied to the gradient amplifier system 42 having Gx, Gy, and Gz amplifiers. Each gradient amplifier excites a corresponding physical gradient coil in a gradient coil assembly, generally designated 50, to produce the magnetic field gradients used for spatially encoding acquired signals. The gradient coil assembly 50 forms part of a magnet assembly 52, which also includes a polarizing magnet 54 (which, in operation, provides a homogeneous longitudinal magnetic field B0 throughout a target volume 55 that is enclosed by the magnet assembly 52) and a whole-body RF coil 56 (which, in operation, provides a transverse magnetic field B1 that is generally perpendicular to B0 throughout the target volume 55). In an embodiment of the invention, RF coil 56 is a multi-channel coil. A transceiver module 58 in the MRI system control 32 produces pulses that are amplified by an RF amplifier 60 and coupled to the RF coil 56 by a transmit/receive switch 62. The resulting signals emitted by the excited nuclei in the patient may be sensed by the same RF coil 56 and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 32 to electrically connect the RF amplifier 60 to the coil 56 during the transmit mode and to connect the preamplifier 64 to the coil 56 during the receive mode. The transmit/receive switch 62 can also enable a separate RF coil (for example, a surface coil) to be used in either transmit mode or receive mode.

After the multi-channel RF coil 56 picks up the RF signals produced from excitation of the target, the transceiver module 58 digitizes these signals. The MRI controller 33 then processes the digitized signals by Fourier transform to produce k-space data, which then is transferred to a memory module 66, or other computer readable media, via the MRI system control 32. “Computer readable media” may include, for example, structures configured so that electrical, optical, or magnetic states may be fixed in a manner perceptible and reproducible by a conventional computer: e.g., text or images printed to paper or displayed on a screen, optical discs, or other optical storage media; “flash” memory, EEPROM, SDRAM, or other electrical storage media; floppy or other magnetic discs, magnetic tape, or other magnetic storage media.

A scan is complete when an array of raw k-space data has been acquired in the computer readable media 66. This raw k-space data is rearranged into separate k-space data arrays for each image to be reconstructed, and each of these is input to an array processor 68 (or multiple processors) which operates to Fourier transform the data into an array of image data. This image data is conveyed through the data link 34 to the computer system 20 where it is stored in memory. In response to commands received from the operator console 12, this image data may be archived in long-term storage or it may be further processed by the image processor 22 and conveyed to the operator console 12 and presented on the display 16.

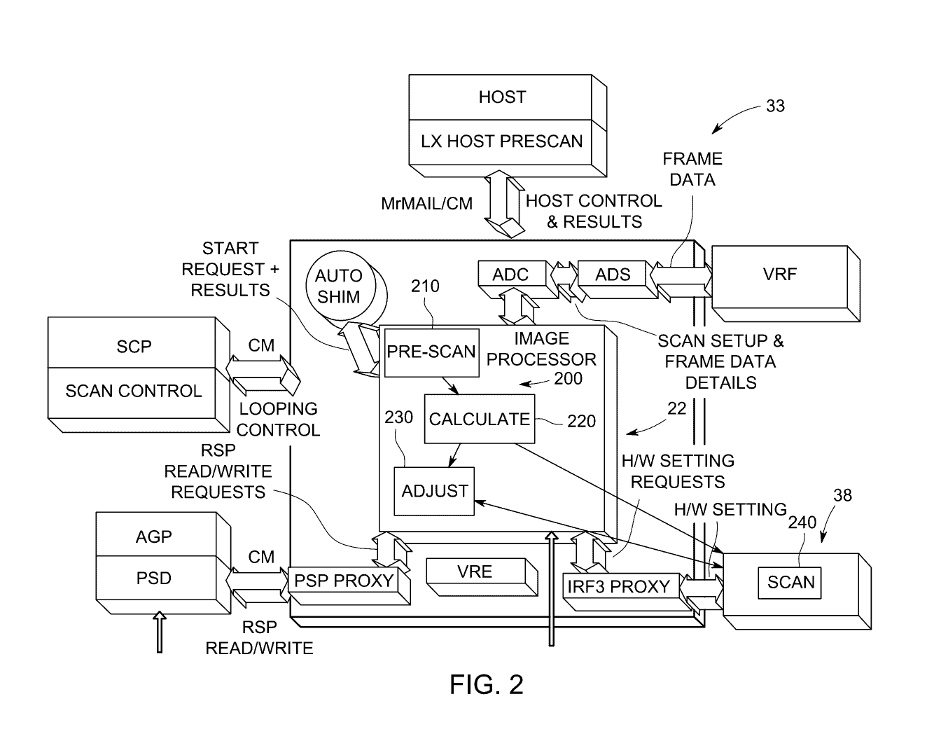

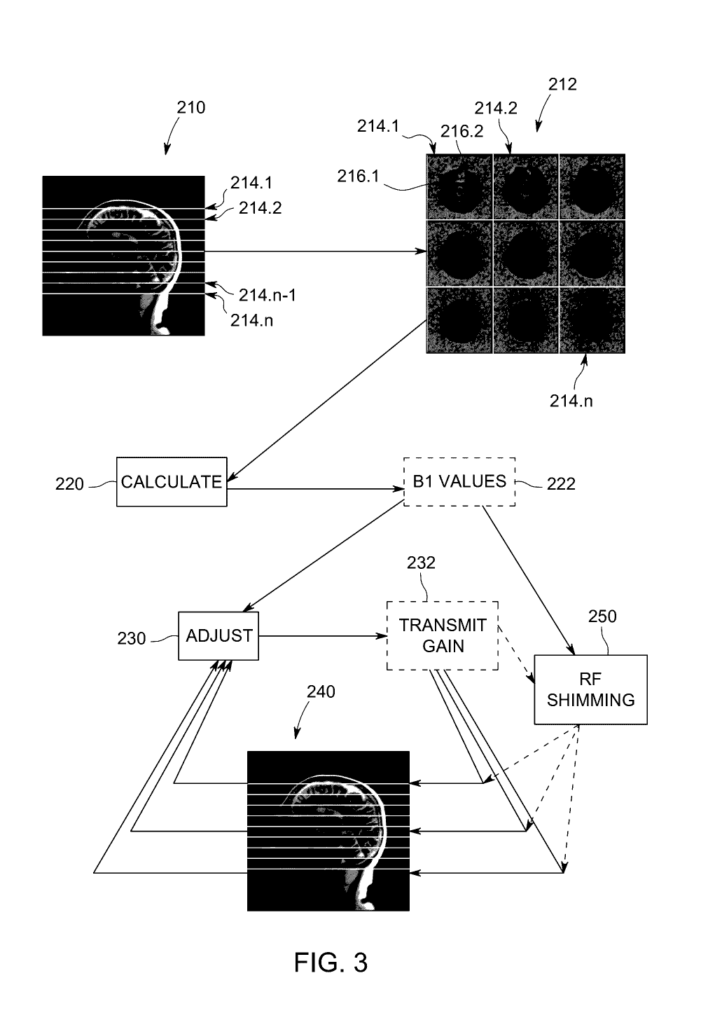

According to embodiments of the invention, as shown in FIGS. 2 and 3, the computer system 32 implements a method 200. For example, the array processor module 68 can be configured to implement the method 200 via the controller 33. The method 200 includes acquiring a multi-slice B1 map 212 during a pre-scan 210 of a target object P; calculating 220 a plurality of B1 values 222 each corresponding to one slice 214.1, 214.2, . . . 214.n of the multi-slice B1 map 212; and adjusting 240 transmit gain 232 before scanning 230 each slice 214.1, 214.2, . . . 214.n of the target object P, according to the B1 value or values 222 calculated for that slice. The plurality of B1 values 222 may include a plurality of arrays of B1 values, for example as indicated by the gray scale shading on the multi-slice B1 map 212, with each array of B1 values corresponding to an array of voxels within one slice of the multi-slice B1 map. Generally, a desirable result of this dynamic or per-slice transmit gain adjustment, is to obtain slice-to-slice uniformity of voxel intensities that correspond to particular tissue types.

In certain embodiments, the method 200 may also include adjusting 230 transmit amplitude and phase (“RF shimming”) among a plurality of transmit coil elements (the multi-channels of the RF coil 56), based upon the B1 maps 212 or values 222 that are calculated for each slice 214 of the multi-slice B1 map 212. In certain embodiments, B1 values 222 may be calculated for one or more subregions 216.1, 216.2, etc. of a slice 214, e.g., for a single voxel or for multiple adjacent voxels within the slice. A subregion 216 may be selected by 1D acquisition during the pre-scan, i.e., pre-selected. Alternatively, a subregion 216 may be selected after the pre-scan as a region of interest within that slice, i.e., post facto identified by an operator among the pre-scan data. Generally, a desirable result of this dynamic or per-slice RF shimming is to enhance consistency of voxel intensity and contrast throughout a given slice.

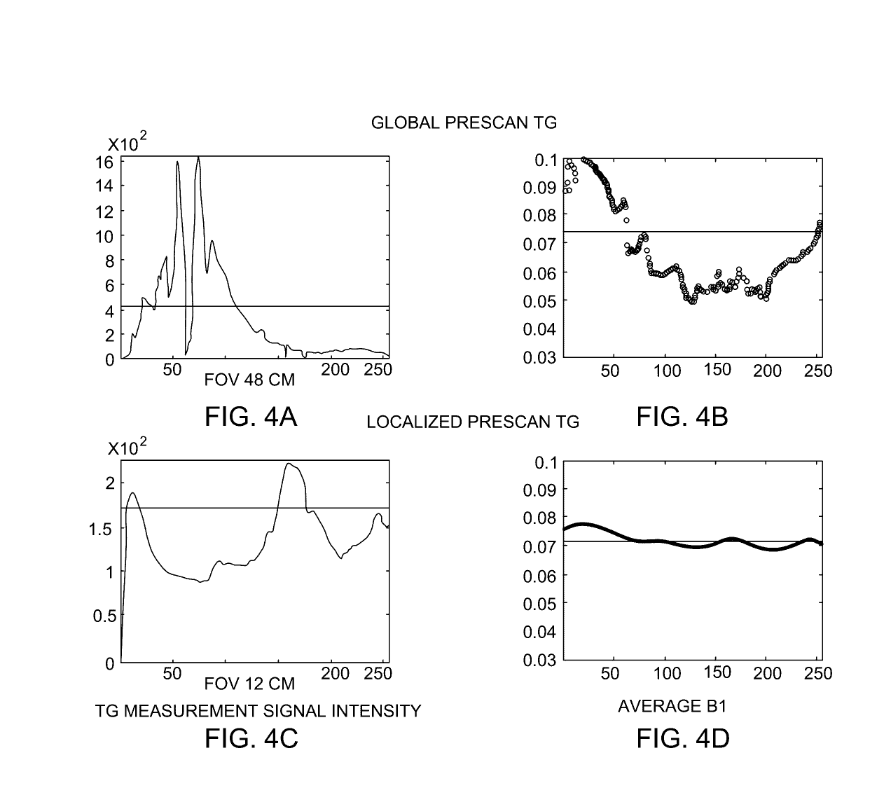

Thus, B1 values 222 are obtained from the pre-scan 210 for an entire target object or region, and are transferred from the pre-scan 210 for use in adjusting 230 transmit gain 232 during the imaging series (scan) 240. This dynamic adjustment of transmit gain reduces variation of receive signal intensity, thereby enhancing image quality. As shown by FIGS. 4A-4D, obtaining B1 values 222 for relatively smaller fields of view (FOVs) during a pre-scan, results in relatively smaller variations of sensed B1 intensity during a subsequent scan. FIGS. 4A and 4C show measurements of transmit gain at different slices during a pre-scan, whereas FIGS. 4B and 4D show averaged values of B1 receive signal at different slices during a scan in which transmit gain was adjusted based on global transmit gain measurements (FIG. 4C) or based on per-slice transmit gain measurements (FIG. 4D). In other words, the per-slice averaged B1 receive signal intensity during a scan remains closer to a median value, as shown in FIG. 4D, due to more-precise measurements during a pre-scan of per-slice B1 variations across a relatively smaller FOV, as shown in FIG. 4C.

Adjusting 230 the transmit gain for each slice 214 of a scan 240 may also include RF shimming 250, so as to obtain different B1 intensities for each of two or more subregions 216 within at least one slice of the scan. In certain embodiments this may include voxel-by-voxel adjustment of transmit gain.

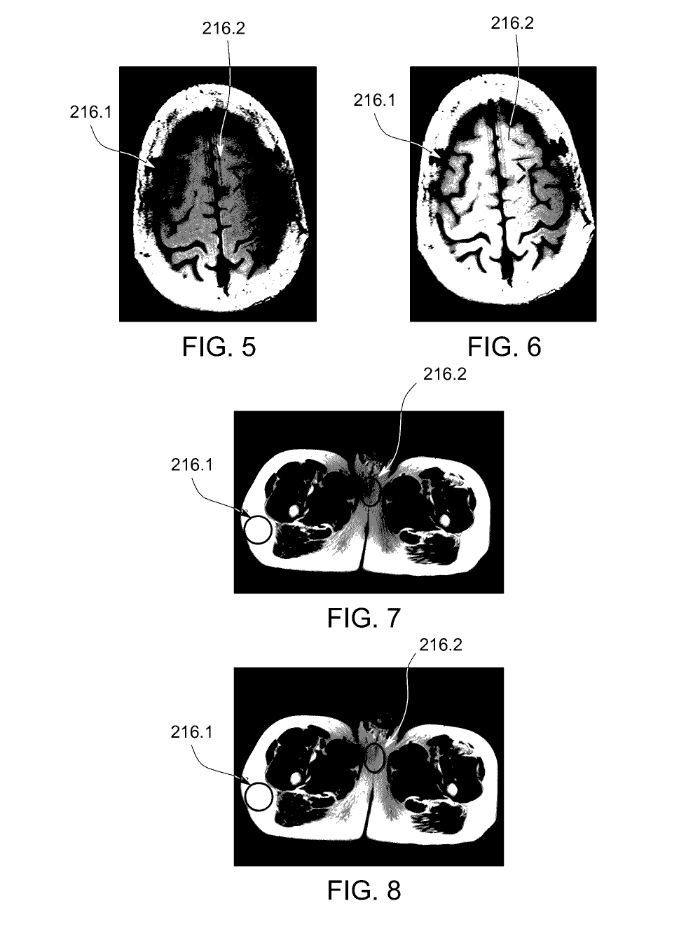

Advantageously, adjustment 230 of transmit gain 232, and/or RF shimming 250, during a scan 240 and based on B1 values 222 obtained from the multi-slices 214 of the pre-scan 210, produces MR images of enhanced clarity and contrast relative to conventional modes of MRI. FIGS. 5 to 8 show two exemplary target objects, and compare results under conventional scans (odd-numbered FIGS. 5 and 7) to results under scans that implement the inventive method 200 (even-numbered FIGS. 6 and 8). As shown, the inventive method 200 of pre-scan measuring transmit gain slice-by-slice (and even optionally by subregions of slices) improves contrast and image clarity especially in subregions 216.1 and 216.2, whereas these areas are shadowed or washed-out in appearance under the conventional scans that used a single global pre-scan measurement of transmit gain.

Thus, embodiments of the invention implement a method for dynamic adjust of transmit gain in magnetic resonance imaging or spectroscopy. The method includes acquiring a multi-slice B1 map during a pre-scan of a target object; calculating a plurality of B1 values each corresponding to one slice of the multi-slice B1 map; and adjusting transmit gain for each slice of a scan of the target object, according to the B1 value or values calculated for that slice. The plurality of B1 values may include a plurality of arrays of B1 values, with each array of B1 values corresponding to an array of voxels within one slice of the multi-slice B1 map. In certain embodiments, for at least one of the slices a B1 value is calculated for a subregion of that slice. For example, the subregion is a single voxel. The subregion may be selected by 1D acquisition during the pre-scan. Alternatively, the subregion may be selected after the pre-scan as a region of interest within that slice. Adjusting transmit gain for each slice of a scan may include adjusting transmit gain differently for each of two or more subregions within at least one slice of the scan. The scan may be an imaging scan, or a spectroscopy scan, or a combination scan.

Other embodiments implement a method for dynamic adjust of RF shimming in magnetic resonance imaging or spectroscopy. The method includes acquiring a multi-slice B1 map during a pre-scan of a target object; calculating a plurality of B1 values each corresponding to one slice of the multi-slice B1 map; and adjusting transmit amplitude and phase among a plurality of transmit coil elements, differently among at least two slices of a multi-slice scan, based upon the plurality of B1 values calculated for the multi-slice B1 map. For example, the plurality of B1 values may include a plurality of arrays of B1 values, and each array of B1 values may correspond to a subregion of a slice within the multi-slice B1 map.

Embodiments of the invention provide an apparatus that includes a controller that is operatively connected with a magnet assembly, which defines a target volume; and an image processor that is configured to acquire a multi-slice B1 map during a pre-scan of a target object within the target volume; calculate a plurality of B1 values each corresponding to one slice of the multi-slice B1 map; and adjust transmit gain for each slice of a scan of the target object, according to the B1 value or values calculated for that slice. The plurality of B 1 values may include a plurality of arrays of B1 values, with each array of B1 values corresponding to an array of voxels within one slice of the multi-slice B1 map. The method may also include adjusting transmit amplitude and phase among a plurality of transmit coil elements, based upon the B1 value or values calculated for each slice of the multi-slice B1 map. In certain embodiments, for at least one of the slices a B1 value is calculated for a subregion of that slice. For example, the subregion is a single voxel. The subregion may be selected by 1D acquisition during the pre-scan. Alternatively, the subregion may be selected after the pre-scan as a region of interest within that slice. Adjusting transmit gain for each slice of a scan may include adjusting transmit gain differently for each of two or more subregions within at least one slice of the scan. The scan may be an imaging scan, or a spectroscopy scan, or a combination scan.

Other embodiments provide an apparatus that includes an image processor that is configured to acquire a multi-slice B1 map during a pre-scan of a target object; calculate a plurality of B1 values each corresponding to one slice of the multi-slice B1 map; and adjust transmit gain for each slice of a scan of the target object, according to the B1 value or values calculated for that slice.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, terms such as “first,” “second,” “third,” “upper,” “lower,” “bottom,” “top,” etc. are used merely as labels, and are not intended to impose numerical or positional requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose several embodiments of the invention, including the best mode, and also to enable one of ordinary skill in the art to practice embodiments of the invention, including making and using any devices or systems and performing any incorporated methods. The patentable scope of the invention is defined by the claims, and may include other examples that occur to one of ordinary skill in the art. Such other examples are intended to be within the scope of the claims if they have structural elements that do not differ from the literal language of the claims, or if they include equivalent structural elements with insubstantial differences from the literal language of the claims.

As used herein, an element or step recited in the singular and proceeded with the word “a” or “an” should be understood as not excluding plural of the elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

Since certain changes may be made in the above-described apparatus and methods, without departing from the spirit and scope of the invention herein involved, it is intended that all of the subject matter of the above description or shown in the accompanying drawings shall be interpreted merely as examples illustrating the inventive concept herein and shall not be construed as limiting the invention.

What is claimed is:

1. A method for dynamic adjust of transmit gain in magnetic resonance imaging or spectroscopy, comprising:
acquiring a multi-slice B1 map during a pre-scan of a target object;
calculating a plurality of B1 values each corresponding to one slice of the multi-slice B1 map; and
adjusting transmit gain for each slice of a multi-slice scan of the target object, according to the B1 value or values calculated for that slice.

2. The method of claim 1 wherein the plurality of B1 values includes a plurality of arrays of B1 values, and each array of B1 values corresponds to an array of voxels within one slice of the multi-slice B1 map.

3. The method of claim 1 wherein for at least one of the slices a B1 value is calculated for a subregion of that slice.

4. The method of claim 3 wherein the subregion is a single voxel.

5. The method of claim 3 wherein the subregion is selected by 1D acquisition during the pre-scan.

6. The method of claim 3 wherein the subregion is selected after the pre-scan as a region of interest within that slice.

7. The method of claim 3 wherein adjusting transmit gain for each slice of a scan includes adjusting transmit gain differently for each of two or more subregions within at least one slice of the scan.

8. A method for dynamic adjust of RF shimming in magnetic resonance imaging or spectroscopy, comprising:
acquiring a multi-slice B1 map during a pre-scan of a target object;
calculating a plurality of B1 values each corresponding to one slice of the multi-slice B1 map; and
adjusting transmit amplitude and phase among a plurality of transmit coil elements, differently among at least two slices of a multi-slice scan, based upon the plurality of B1 value or values calculated for each slice of the multi-slice B1 map.

9. The method of claim 8 wherein the plurality of B1 values includes a plurality of arrays of B1 values, and each array of B1 values corresponds to a subregion of a slice within the multi-slice B1 map.

10. An apparatus comprising:
a controller that is operatively connected with a magnet assembly, which defines a target volume; and
an image processor that is configured to:
acquire a multi-slice B1 map during a pre-scan of a target object within the target volume;
calculate a plurality of B1 values each corresponding to one slice of the multi-slice B1 map; and
adjust at least one of transmit gain or RF shimming for each slice of a multi-slice scan of the target object, according to the B1 value or values calculated for that slice.

11. The apparatus of claim 10 wherein the plurality of B1 values includes a plurality of arrays of B1 values, and each array of B1 values corresponds to an array of voxels within one slice of the multi-slice B1 map.

12. The apparatus of claim 10, configured to adjust RF shimming, differently among at least two slices of the multi-slice scan, based upon the B1 value or values calculated for each slice of the multi-slice B1 map.

13. The apparatus of claim 12 wherein for at least one of the slices of the multi-slice B1 map a B1 value is calculated for a subregion of that slice.

14. The apparatus of claim 13 wherein the subregion is a single voxel.

15. The apparatus of claim 13 wherein the subregion is selected by 1D acquisition during the pre-scan.

16. The apparatus of claim 10 wherein for at least one of the slices of the multi-slice B1 map a B1 value is calculated for a subregion of that slice.

17. The apparatus of claim 13 wherein the subregion is selected after the pre-scan as a region of interest within that slice.

18. The apparatus of claim 10 wherein adjusting transmit gain for each slice of a scan includes adjusting transmit gain differently for each of two or more subregions within at least one slice of the scan.

19. The apparatus of claim 10 wherein the scan is an imaging scan.

20. An apparatus comprising:
an image processor that is configured to:
acquire a multi-slice B1 map during a pre-scan of a target object;
calculate a plurality of B1 values each corresponding to one slice of the multi-slice B1 map; and
adjust at least one of transmit gain or RF shimming for each slice of a multi-slice scan of the target object, according to the B1 value or values calculated for that slice.
